(19) United States
(12) Patent Application Publication
(10) Pub. No.: US 2012/0247530 A1
(43) Pub. Date: Oct. 4, 2012

(54) Strain relief solar cell electric coupler

(76) Inventors: Dmitry Dimov, San Francisco, CA (US); Steven Weston Frehn, San Francisco, CA (US); Denis Shcheglov, San Leandro, CA (US); Mark Alan Goldman, Menlo Park, CA (US)

(21) Appl. No.: 13/506,232

(22) Filed: Apr. 4, 2012

Related U.S. Application Data
(60) Provisional application No. 61/516,481, filed on Apr. 4, 2011.

(51) Int. Cl. H01L 31/05

(52) U.S. Cl. 136/244

(57) ABSTRACT

The device described relates to a strain reliving electric coupler used to connect solar cells in solar panels, particularly solar panels made from polymer materials and lightweight metals. These couplers can withstand high levels of thermal expansion and contraction during manufacturing and over years of outdoor exposure.

### CROSS-REFERENCE TO RELATED APPLICATIONS

This application claims priority to U.S. Provisional App. No. 61/516,481, filed 4 Apr. 2011, which is incorporated by reference herein in its entirety.

### BACKGROUND OF THE INVENTION

1. Field of the Invention

Devices and methods used to connect solar cells in a solar panel are disclosed. More particularly, electric coupling devices that can be used in solar panels that comprise polymers and metal with high coefficients of linear thermal expansion are disclosed.

2. Description of the Related Art

Current photovoltaic (PV) solar panels are made using glass as a superstrate. The glass superstrate functions as a moisture barrier, provides impact resistance and acts as a rigid structural surface to which PV solar cells are bonded using encapsulants, such as ethylene vinyl acetate (EVA). In addition to these qualities, glass is used because glass and silicon solar cells have similar coefficients of linear thermal expansion. Most solar panels are used outdoors and exposed to considerable thermal stress over the course of many years. Regular and continued thermal expansion and contraction strain the interconnects that electrically link cells in a PV panel. Glass has a low coefficient of thermal expansion and keeps the interconnects from experiencing high stress.

While glass can be a good supersaturate for a PV panel, there are inherent problems with its fragility, weight and other constraints, such as manufacturing limitations. Glass solar panels are heavy, can be difficult to handle and can break when installed. Many roof structures cannot support the weight of standard glass solar panels. Solar panel manufacturing facilities are frequently located close to glass manufacturing facilities to avoid excess shipping expenses.

Using polymeric superstrates instead of glass solves these problems. Polymeric superstrates can reduce the weight of a solar panel by a factor of 2 to 4 per unit area or per unit of electrical output. This reduction in weight allows for lower shipping costs, easier handling during installation, manufacturing, and shipment, and less breakage throughout the supply chain. Polymer films such as ETFE and FEP can withstand impacts and other stresses that glass materials used in solar panels, such as float glass, cannot tolerate.

Replacing glass with polymer films, despite its advantages, can present new engineering problems. Removing glass reduces the rigidity of the solar panel and makes solar cells more subject to environmental stresses, in particular thermal expansion. Because glass is not present to provide a rigid structural layer, a rigid substrate or some other framework becomes necessary to provide stiffness in order to protect the panel from flexing, bending and other stresses that could damage the panel or solar cells. Removing the metal frame present in standard PV panels further increases the need for a replacement structural element in the panel.

Lightweight building materials, such as architectural composite panels, present an attractive alternative to glass superstrates and metal frames. Such panels can be used as a substrate that provides structure and rigidity without being heavy. These panels can comprise aluminum and polypropylene.

When polymeric materials are used as superstrates and architectural composite panels are used as substrates with standard monocrystalline solar cells that have been interconnected in series, the electrical interconnections can break during the desired useful life of the panel due to a variety of failure modes or stresses, including thermal expansion and contraction, flexing, vibrations, impact, weathering and other damage or use. When solar panels expand and contract due to temperature changes, a bend or other stress points can develop along electrical interconnection points. Mechanical stresses can become concentrated at these bends and stress points. After repeated cycles of expansion and contraction, the interconnection wire, typically made of copper coated with tin or tin alloy, can break at the bend or stress point, causing the entire “string,” or series of interconnected cells, to fail and no longer produce and transmit electricity to the remaining functioning parts of the solar panel.

### SUMMARY OF THE INVENTION

A solar cell system is disclosed. The solar cell system can have a first solar cell, a second solar cell, and an electric coupler. The second solar cell can be adjacent to the first solar cell. The electric coupler can have a conductive spring. The electric coupler can electrically connect the first solar cell to the second solar cell. The spring can have a first peak. The first peak can have a first profile. The first profile can have a first radius of curvature from about 1 mm⁻¹ to about 5 mm⁻¹.

The electric coupler can have a width from about 0.5 mm to 3.5 mm. The electric coupler can have a height from about 0.5 mm to about 2 mm. The electric coupler can have a length from about 3 mm to about 7 mm. The electric coupler can have a radius from about 0.2 mm to about 1 mm. The electric coupler can have a thickness from about 0.05 mm to about 0.2 mm.

The electric coupler can have a second peak. The electric coupler can have a lead-in peak over the edge of the first solar cell. The lead-in peak can be spaced from the first solar cell by a lead-in gap. The lead-in gap can be from about 0.1 mm to about 0.5 mm.

A solar panel is disclosed that can have a first solar cell, a second solar cell, an electric coupler and a first layer. The second solar cell can be adjacent to the first solar cell. The electric coupler can have a spring. The electric coupler can electrically connect the first solar cell to the second solar cell. The first layer can have a polymer material.

The panel can have a second layer. The second layer can have a polymer. The panel can have a third layer. The third layer can have a metal.

The first layer can have a linear coefficient of thermal expansion from about about 3×10⁻⁶ m/m° C. to 40×10⁻⁶ m/m° C. The second layer can have a linear coefficient of thermal expansion from about 3×10⁻⁶ m/m° C. to 40×10 m/m° C. The third layer can have a linear coefficient of thermal expansion ranging from about 3×10 ⁻⁶ m/m° C. to 40×10⁻⁶ m/m° C.

### BRIEF DESCRIPTION OF THE FIGURES

FIG. 1 illustrates a solar panel with photovoltaic cells and electric couplers. The couplers can be placed between photovoltaic cells or between cells and bus bar leads and/or other electrical interconnections.

FIG. 2 illustrates a closeup of section of FIG. 1 and shows where an electric coupler can be located in relation to a solar cell or a bus bar.

FIG. 3 illustrates a perspective view of the electric coupler between photovoltaic cells.

FIG. 4 illustrates a side view of the electric coupler between solar cells, with the height and length of an electric coupler denoted.

FIG. 5 illustrates a cross-section of the electric coupler with thickness and width of the interconnection wire, or electrical lead material, denoted.

FIG. 6 illustrates a sample profile of the electric coupler and its radius of curvature.

FIG. 7A illustrates a variation of the electric coupler attached to the bottom surface of a first solar cell and the top surface of a second solar cell.

FIG. 7B illustrates a variation of the electric attached to the top surface of a first solar cell and the bottom surface of a second solar cell.

FIG. 7C illustrates a variation of the electric coupler attached to one face of a first solar cell and to the same face of a second solar cell.

FIG. 7D illustrates a peak shape of the electric coupler having one radius of curvature.

FIG. 7E illustrates a peak shape of the electric coupler having another radius of curvature.

FIG. 7F illustrates a peak shape of the electric coupler having a third exemplary radius of curvature.

FIG. 7G illustrates a variation of the electric coupler with an overall oval profile.

FIG. 7H illustrates a variation of the electric coupler with an overall rectangular profile.

FIG. 7I illustrates a variation of the electric coupler with an overall hourglass profile.

FIG. 7J illustrates a variation of the electric coupler with an overall triangular profile.

FIG. 8 illustrates the cross section of a solar panel with solar cells, an electric coupler, polymer layers, and metal layers.

FIG. 9 illustrates the change in various dimensions of the electric coupler due to thermal expansion under different temperature fluctuations.

FIG. 10 illustrates a side view of the lead-in peak at either end of the electric coupler where it can attach to a solar cell.

FIG. 11 illustrates a manufacturing process to form the electric coupler.

### DETAILED DESCRIPTION

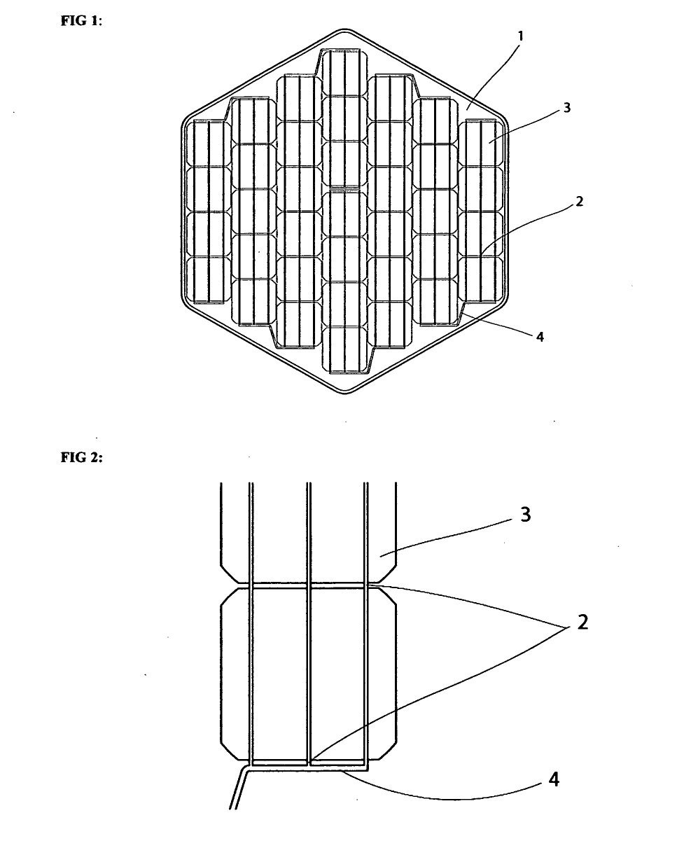

An electric coupler 2 that can be used to electrically link solar cells 3 in a solar panel is disclosed. The solar panel 1 comprises metallic and polymeric materials. The electric coupler 2 can electrically link solar cells 3 to other solar cells and/or to bus bars 4. FIG. 1 illustrates where the electric coupler 2 can be placed in relation to solar cells 3 and bus bars 4 in a solar panel 1.

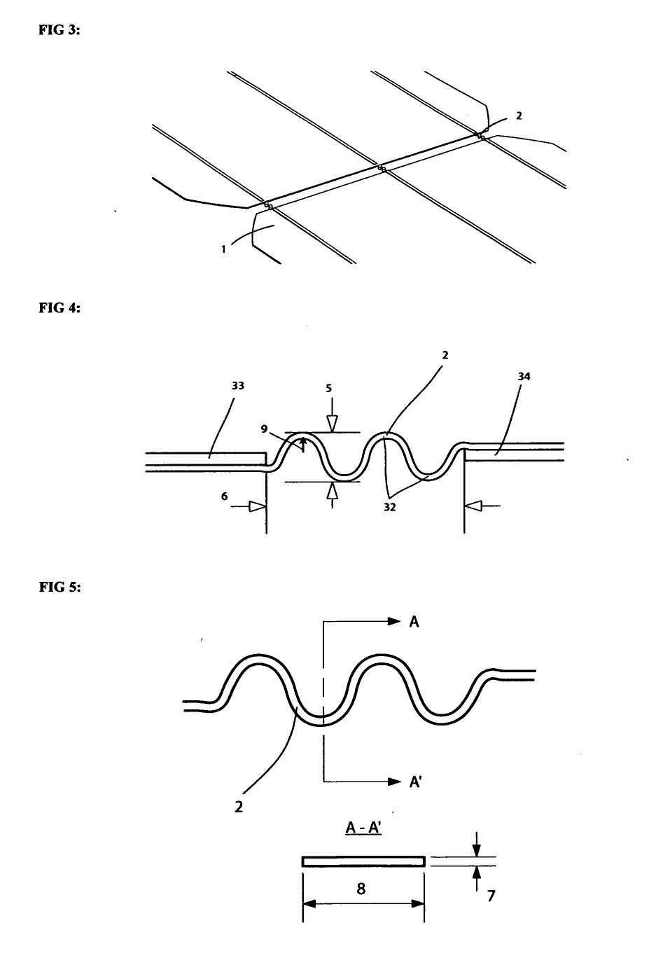

The FIG. 2 shows a closer view of where the electric coupler 2 can interconnect solar cells 3 and bus bars 4. FIG. 3 illustrates a perspective view of the electric coupler 2 and where it can be positioned between solar cells 1.

FIG. 4 illustrates a side view of the electric coupler 2 and the length and height of the portion of the electric coupler between solar cells 33, 34. The electric coupler 2 can act as a spring, or strain relieving device, along the length 6 of the electric coupler between cells while still conducting electricity. Stress or strain can be induced by various factors, including linear thermal expansion during normal outdoor use or manufacturing of a solar panel. The length 6 of the electric coupler 2 is 3 mm to 7 mm, more narrowly 4 mm to 6 mm. The height 5 of the electric coupler 2 is 0.5 mm to 2 mm, more narrowly 0.8 mm to 1.2 mm. The electric coupler 2 comprises a spring with a multiplicity of peaks 32. The peaks 32 can have a radius 9 of 0.2 mm to 1 mm, more narrowly 0.4 mm to 0.6 mm. The aforementioned shape can be described as semicircular.

FIG. 5 illustrates a cross-sectional view of the electric coupler 2. The width 8 of the electric coupler 2 is 0.5 mm to 3.5 mm, more narrowly 1.5 mm to 2.5 mm. The thickness 7 is 0.05 mm to 0.2 mm.

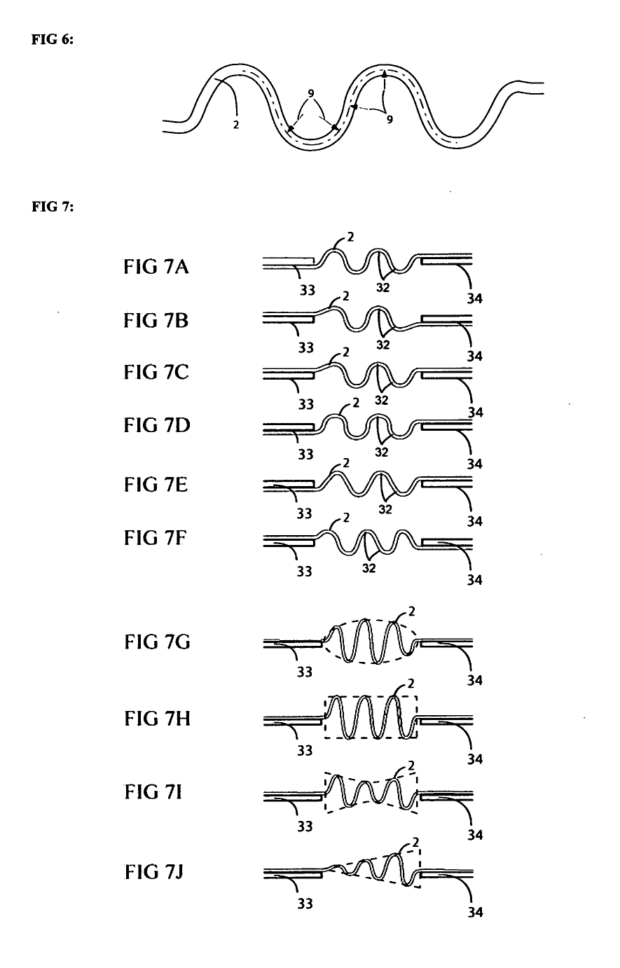

FIG. 6 illustrates the profile of the electric coupler 2. The profile has a curvature from 1 mm⁻¹ to 5 mm⁻¹. Curvature is defined as k=1/R, where “k” is the curvature and “R” is the radius 9 of any point on the peak.

FIG. 7 illustrates multiple variations of the electric coupler 2 between solar cells 33, 34. FIG. 7A illustrates one variation of the electric coupler 2 attached to the bottom surface of the first solar cell 33 and the top surface of the second solar cell 34. FIG. 7B illustrates another variation of the electric coupler 2 with the electric coupler attached to the top surface of the first solar cell 33 and the bottom surface of the second solar cell 34. FIG. 7C illustrates a variation of the electric coupler 2 attached to the top surface of the first solar cell 33 and the top surface of the second solar cell 34. The electric coupler could alternatively be attached to the bottom face of a first solar cell and the bottom face of a second solar cell. FIG. 7D illustrates a variation of the profile of the electric coupler 2 wherein the peaks 32 of the electric coupler have a radius (9 in FIG. 6) of curvature from 1 mm⁻¹ to 5 mm⁻¹. FIG. 7E illustrates a second variation of the profile of the electric coupler 2 wherein the peaks 32 of the electric coupler have a radius of curvature from 1 mm⁻¹ to 5 mm⁻¹. FIG. 7F illustrates a third variation of the profile of the electric coupler 2 wherein the peaks 32 of the electric coupler have a radius of curvature from 1 mm⁻¹ to 5 mm⁻¹. FIG. 7G illustrates a variation of the electric coupler 2 between a first solar cell 33 and a second solar cell 34 wherein the overall profile of the electric coupler is ascending and descending, or oval in shape. FIG. 7H illustrates a variation of the electric coupler 2 wherein the overall profile is constant, or rectangular in shape. FIG. 7I illustrates a variation of the electric coupler 2 wherein the overall profile is descending then ascending, or hourglass shaped. FIG. 7J illustrates a variation of the electric coupler 2 wherein the overall profile is ascending, or triangular, in shape. The electronic coupler could similarly be descending in shape, or triangular in the opposite direction.

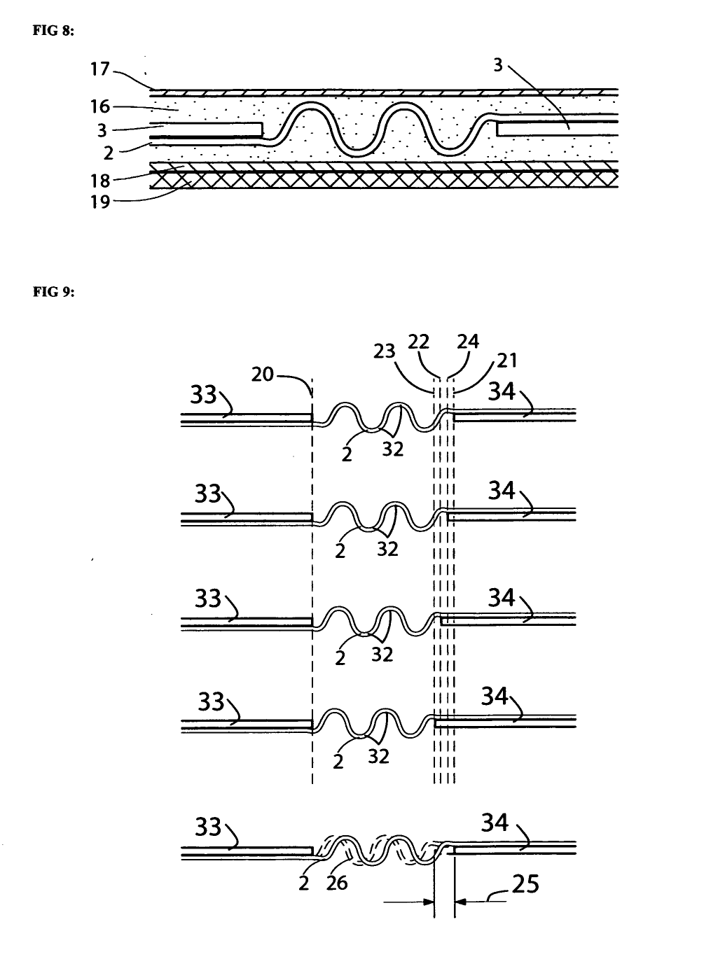

FIG. 8 illustrates a cross sectional close-up view of an electric coupler 2 and two solar cells 3 that are encased in an encapsulant 16 such as ethylene vinyl acetate (EVA) or other materials. Also shown is a first polymer layer 17 that acts as a superstrate. The first layer 17 can be made of polymer films such as ethylene tetrafluoroethylene (ETFE), fluorinated ethylene propylene (FEP) or other materials. Also shown is a second layer 18 and a third layer 19 that can act as a rigid substrate, or structural support layer. The second layer 18 can be made of metal such as aluminum, polymers such as polypropylene, or other materials. The third layer 19 can be made of metal such as aluminum, polymers such as polypropylene, or other materials. The substrate can be a laminate, or composite of multiple layers of materials manufactured into a single structural layer. Additional layers of materials can be added to the second layer 18 and the third layer 19 to form a composite laminate. The first layer 17, the second layer 18, and the third layer 19 can have coefficients of linear thermal expansion from 3×10⁻⁶ m/m° C. to 40×10⁻⁶ m/m° C. During lamination, the second layer 18 and third layer 19 will expand more than solar cells 3. The electric coupler 2 can expand or contract to adjust to the changing distance between solar cells 3 without breaking.

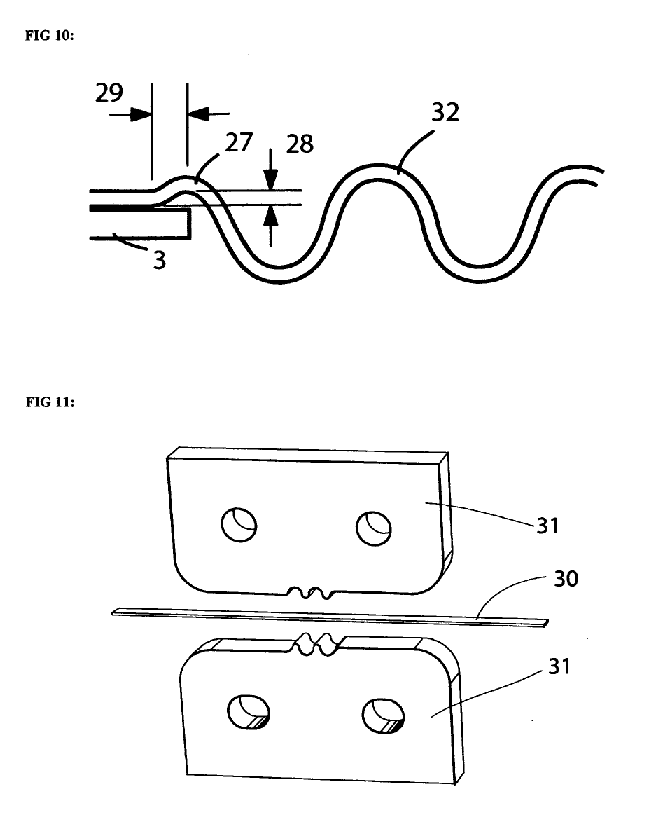

FIG. 9 shows a cross sectional view of an electric coupler 2 in multiple positions 21, 22, 23, 24 while a first solar cell 33 and a second solar cell 34 change relative position due to various factors, including linear thermal expansion. A first solar cell 33 is shown at a fixed position 20. A second solar cell 34 is shown which can change relative position while the entire solar panel (FIG. 1, 1) experiences temperature fluctuations or other movement. The second solar cell 34 can move to a contracted position 23 when it experiences a low temperature, such as −40° C. The solar cell 34 can move to an extended position 24 when it experiences a high temperature, such as 90° C. The peaks 32 in the electric coupler 2 are able to absorb the thermal strain caused by expansion and contraction over such temperatures. An electric coupler 2 with peaks 32 that are within the dimensions previously listed can last over 1000 thermal expansion and contraction cycles at similar temperatures to those mentioned above.

FIG. 9 further illustrates how a first solar cell 33 and a second solar cell 34 can contract and move position in common manufacturing processes, in particular lamination, or the combined application of heat and pressure in manufacturing. A solar panel can be laminated at temperatures as high as 170° C. for as much as 10 to 20 minutes and then be exposed to ambient temperatures of about 25° C. after lamination. Glass and silicon have low, and similar, coefficients of thermal expansion. Solar panels that contain aluminum can have coefficients of thermal expansion that are three to four times higher than that of glass. The peaks 32 in the electric coupler 2 can absorb the thermal contraction that follows the lamination process. During lamination, the solar cell 34 moves to a heat-expanded position 21. After lamination, when the panel cools, the solar cell 34 moves to a contracted position 22 at ambient temperature. The distance between cells can decrease from the expanded state by a value that is dependent on the other layers in the panel, such as polymers and aluminum in a substrate material (as described in FIG. 8). This distance can be on the order of 0.5 mm for each electric coupler 2. The electric coupler 2 is able to expand and compress along throughout the range of expansion and contraction 25 without breaking. The peaks of the electrical coupler can change shape as well as distance, or flex, 26, without breaking.

FIG. 10 illustrates an electric coupler 2 that comprises a lead-in peak 27 that gradually increases slope as the electric coupler 2 transitions into the larger peaks 32. The lead-in peak 27 can act as a visual marker for placement of the electric coupler 2 in relation to the solar cell 3 during manufacturing. The lead-in peak 27 can protect the edge of the solar cell 3 during manufacturing, in particular during the lamination process, when a solar panel can undergo pressurization of 1 atmosphere or more. The lead-in peak 27 can avoid the edge of the solar cell 3 so that the pressure will not force the electric coupler 2 onto the edge of the solar cell 3 and break it. The height 28 of the lead-in peak is 0.5 mm to 1 mm. The length 29 of the lead-in peak is 0.5 mm to 3 mm.

FIG. 11 illustrates a manufacturing process for the electric coupler 2. The electric coupler 2 can be made from a flat copper wire 30 coated with a tin alloy. The peaks can be stamped into the wire 30 using a die 31. The die 31 can be used on a machine capable of clamping the two parts of the die together and feeding the wire 30 through the die 31, such as a bus bar cutting machine, or a tabber-stringer, on a typical automated solar production line.

It is apparent to one skilled in the art that various changes and modifications can be made to this disclosure, and equivalents employed, without departing from the spirit and scope of the invention. Elements of systems, devices and methods shown with any embodiment are exemplary for the specific embodiment and can be used in combination or otherwise on other embodiments within this disclosure.

We claim:

1. A solar cell system comprising:
a first solar cell;
a second solar cell adjacent to the first solar cell;
an electric coupler comprising a conductive spring, wherein the coupler electrically connects the first solar cell to the second solar cell;
wherein the spring has a first peak; and
wherein the first peak has a first profile, and wherein the first profile has a first curvature from 1 mm⁻¹ to 5 mm⁻¹.

2. The system of claim 1, wherein the coupler has a width from 0.5 mm to 3.5 mm.

3. The system of claim 1, wherein the coupler has a height from 0.5 mm to 2 mm.

4. The system of claim 1, wherein the coupler has a length from 3 mm to 7 mm.

5. The system of claim 1, wherein the coupler has a radius from 0.2 mm to 1 mm.

6. The system of claim 1, wherein the coupler has a thickness from 0.05 mm to 0.2 mm.

7. The system of claim 1, wherein the coupler comprises a second peak.

8. The system of claim 1, wherein the coupler has a lead-in peak over the edge of the first solar cell.

9. The system of claim 8, wherein the lead-in peak is spaced from the first solar cell by a lead-in gap, and wherein the lead-in gap is from 0.1 mm to 0.5 mm. The system of claim 1, wherein the lead-in peak is spaced from the cell by a lead-in gap, and wherein the lead-in gap is from 0.1 mm to 0.5 mm.

10. A solar panel comprising:
a first solar cell;
a second solar cell adjacent to the first solar cell;
an electric coupler comprising a spring, wherein the electric coupler electrically connects the first solar cell to the second solar cell;
a first layer comprising a polymer material.

11. The solar panel of claim 10, further comprising a second layer comprising a polymer.

12. The solar panel of claim 11, further comprising a third layer comprising a metal.

13. The solar panel of claim 10, wherein the first layer has a linear coefficient of thermal expansion from 3×10⁻⁶ m/m° C. to 40×10⁻⁶ m/m° C.

14. The solar panel of claim 10, further comprising a second layer having a linear coefficient of thermal expansion from 3×10 m/m° C. to 40×10⁶ m/m° C.

16. The solar panel of claim 10, further comprising a third layer having a linear coefficient of thermal expansion from 3×10⁻⁶ m/m° C. to 40×10⁻⁶ m/m° C.
